(19) United States
(12) Patent Application Publication
(10) Pub. No.: US 2026/0327778 A1
(43) Pub. Date: Oct. 22, 2026

(54) DEPOSITION MASK, METHOD OF MEASURING GAP USING THE SAME, AND ELECTRONIC DEVICE MANUFACTURED USING THE SAME

(71) Applicant: Samsung Display Co., Ltd., Yongin-si (KR)

(72) Inventor: Sung Woon KIM, Yongin-si (KR)

(21) Appl. No.: 19/354,125

(22) Filed: Oct. 9, 2025

(30) Foreign Application Priority Data
Apr. 21, 2025 (KR) 10-2025-0051856

(51) Int. Cl. C23C 14/04; G01B 11/14

(52) U.S. Cl. CPC C23C 14/042; G01B 11/14

(57) ABSTRACT

A deposition mask includes: a base layer including silicon; an inorganic layer on the base layer, wherein the inorganic layer comprises an opening pattern in a pattern area, and lens patterns in a non-pattern area excluding the pattern area and having different focal lengths.

### CROSS-REFERENCE TO RELATED APPLICATION

The present application claims priority to and the benefit of Korean Patent Application Number 10-2025-0051856, filed on Apr. 21, 2025, in the Korean Intellectual Property Office, the entire disclosure of which is incorporated herein by reference.

### BACKGROUND

### 1. Field

Aspects of some embodiments of the present disclosure relate to a display device.

### 2. Description of the Related Art

Recently, as consumer interest in information display has increased, research and development on display devices have been continuously carried out.

The above information disclosed in this Background section is only for enhancement of understanding of the background and therefore the information discussed in this Background section does not necessarily constitute prior art.

### SUMMARY

Aspects of some embodiments of the present disclosure relate to a display device. For example, aspects of some embodiments of the present disclosure relate to a deposition mask for manufacturing the display device, a method of measuring a gap using the deposition mask, and an electronic device including the display device manufactured using the deposition mask.

Aspects of some embodiments of the present disclosure include a deposition mask with relatively improved reliability of a deposition process by uniformizing a gap between the deposition mask and a mother substrate.

Aspects of some embodiments of the present disclosure include a method of measuring a gap using the deposition mask.

Aspects of some embodiments of the present disclosure include an electronic device including a display device manufactured using the method of measuring the gap.

According to some of embodiments of the present disclosure, a deposition mask may include a base layer including silicon, an inorganic layer arranged on the base layer, wherein the inorganic layer comprises an opening pattern located in a pattern area, and lens patterns located in a non-pattern area excluding the pattern area and having different focal lengths.

According to some embodiments, each of the lens patterns having the different focal lengths may include a nano-pattern including patterns having a nanoscale size.

According to some embodiments, the lens patterns having the different focal lengths may include nano-patterns of different densities, respectively.

According to some embodiments, the lens patterns having the different focal lengths may include nano-patterns of different areas, respectively.

According to some embodiments, each of the lens patterns having the different focal lengths may include a nano-pattern including patterns of different areas.

According to some embodiments, the lens patterns having the different focal lengths may include nano-patterns having different thicknesses, respectively.

According to some embodiments, each of the patterns included in the nano-pattern may be defined as a recess.

According to some embodiments, each of the patterns included in the nano-pattern may be defined as a protrusion.

According to some embodiments, the inorganic layer may include titanium dioxide (TiO₂).

According to some embodiments of the present disclosure, a method of measuring a gap may include aligning a mother substrate including mark patterns located at positions corresponding to lens patterns on a deposition mask including an opening pattern located in a pattern area, and the lens patterns located in a non-pattern area excluding the pattern area and having different focal lengths, irradiating light in a direction from the deposition mask toward the mother substrate, and deriving a gap between the deposition mask and the mother substrate using a focal length of a lens pattern in which a focus is formed on a corresponding mark pattern among the lens patterns.

According to some embodiments, each of the lens patterns may include a nano-pattern including patterns having a nanoscale size.

According to some embodiments, the focal length of the lens pattern may be controlled by adjusting at least one of a density of the nano-pattern, an area of the nano-pattern, or a thickness of the nano-pattern.

According to some embodiments, the mother substrate may include a display cell located in an active area, and the mark patterns located in an inactive area excluding the active area and having different shapes.

According to some embodiments, in the aligning of the mother substrate on the deposition mask, the mother substrate may be positioned on the deposition mask such that the pattern area and the active area overlap with each other, and the lens patterns and the mark patterns overlap with each other.

According to some embodiments, a number of lens patterns and a number of mark patterns may be the same.

According to some embodiments, the light may have a wavelength of 1050 nanometers or greater.

According to some embodiments, the light may be visible light.

According to some embodiments, the deposition mask may include: a base layer including silicon, and an inorganic layer arranged on the base layer and defining the opening pattern and the lens patterns, wherein the lens patterns are spaced apart from the base layer in a plane.

According to some of the present disclosure, an electronic device may include a processor, and a display device displaying an image under control of the processor, wherein the display device is manufactured using the deposition mask.

### BRIEF DESCRIPTION OF THE DRAWINGS

The above and other aspects and features of embodiments according to the present disclosure will become more apparent by describing, in further detail, aspects of some embodiments thereof with reference to the accompanying drawings, in which:

FIG. 1 is a side view illustrating aspects of a deposition apparatus, according to some embodiments;

FIG. 2 is a plan view illustrating aspects of a deposition mask of FIG. 1, according to some embodiments;

FIG. 3 is a plan view illustrating aspects of the mother substrate of FIG. 1, according to some embodiments;

FIG. 4 is a cross-sectional view illustrating aspects of a deposition mask of FIG. 2, according to some embodiments;

FIG. 5 is a plan view illustrating lens patterns having different focal lengths of FIG. 2;

FIG. 6 is a cross-sectional view taken along the line I-I′ of FIG. 5;

FIG. 7 shows further details of a cross-sectional view taken along the line I-I′ of FIG. 5, according to some embodiments ;

FIG. 8 is a plan view illustrating further details of lens patterns according to some embodiments;

FIG. 9 is a plan view illustrating further details of lens patterns according to some embodiments;

FIG. 10 is a plan view illustrating further details of a lens pattern according to some embodiments;

FIG. 11 is a diagram illustrating a method of measuring a gap between a mother substrate and a deposition mask according to some embodiments of the present disclosure;

FIG. 12 is a plan view illustrating further details of a lens pattern according to some embodiments;

FIG. 13 is a cross-sectional view illustrating further details of a method of measuring a gap between a mother substrate and a deposition mask according to some embodiments of the present disclosure;

FIG. 14 is a cross-sectional view illustrating further details of a method of measuring a gap between a mother substrate and a deposition mask according to some embodiments of the present disclosure;

FIG. 15 is a block diagram of an electronic device according to some embodiments; and

FIG. 16 shows schematic views of various embodiments of the electronic device.

### DETAILED DESCRIPTION

The disclosure may be modified in various manners and have various forms. Therefore, specific embodiments will be illustrated in the drawings and will be described in detail in the specification. However, it should be understood that the disclosure is not intended to be limited to the disclosed specific forms, and the disclosure includes all modifications, equivalents, and substitutions within the spirit and technical scope of the disclosure.

Similar reference numerals are used to designate like components throughout the drawings. In the accompanying drawings, the dimensions of structures may be exaggerated relative to actual dimensions for clarity of illustration. Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component.

It should be understood that in the present application, a term of “include”, “have”, or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. Furthermore, in case that a first part such as a layer, a film, a region, or a plate is arranged “on” a second part, the first part may be not only “directly on” the second part but a third part may intervene between them. In addition, when it is expressed that a first part such as a layer, a film, a region, or a plate is formed on a second part, the surface of the second part on which the first part is formed is not necessarily limited to an upper surface of the second part but may include other surfaces such as a side surface or a lower surface of the second part. To the contrary, in case that a first part such as a layer, a film, a region, or a plate is “under” a second part, the first part may be not only “directly under” the second part but a third part may intervene between them.

Hereinafter, aspects of some embodiments of the invention and other matters necessary for those skilled in the art to readily understand the invention will be described in more detail with reference to the accompanying drawings. In the following description, the singular expressions include plural expressions unless the context clearly dictates otherwise.

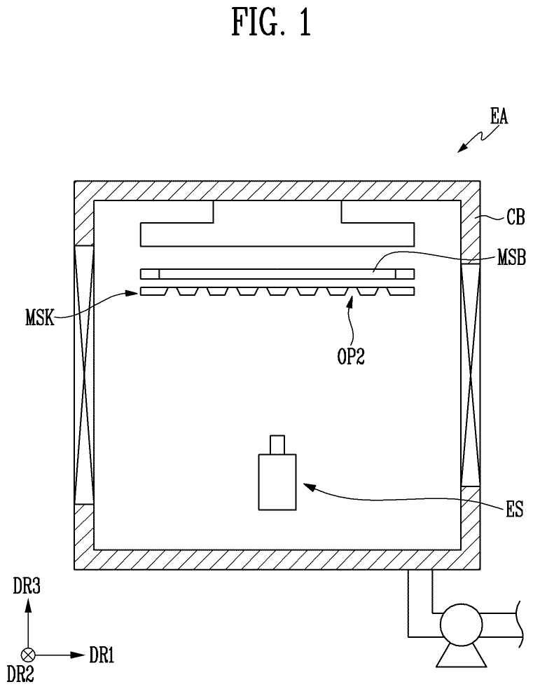

FIG. 1 is a side view illustrating aspects of a deposition apparatus EA according to some embodiments.

Referring to FIG. 1, the deposition apparatus EA according to some embodiments may include a chamber CB, a deposition source ES, and a deposition mask MSK.

The chamber CB may have an interior space. The interior space of the chamber CB may be a workspace provided for a deposition process. An object which is the subject of the deposition may be received (or arranged) in the chamber CB. For example, a mother substrate MSB which is the object of deposition may be arranged or placed in the interior of the chamber CB.

The deposition source ES may be arranged or located inside the chamber CB. The deposition source ES may receive a deposition material and may supply the deposition material to the interior space of the chamber CB. The deposition material may include a material which forms a pattern layer (e.g., a set or predetermined pattern layer) (e.g., a light emitting layer) on the mother substrate MSB. The deposition source ES may apply energy (e.g., thermal energy, light energy, or vibrational energy) to the deposition material to vaporize or sublimate the deposition material. According to some embodiments, the deposition source ES may include an internal heater, and operation of the heater may melt or sublimate the deposition material by heating the deposition material inside the deposition source ES. The deposition source ES may be replaceable. The deposition source ES may be replaced with a new deposition source when the stored deposition material is exhausted.

The deposition mask MSK may be arranged or placed between the mother substrate MSB and the deposition source ES.

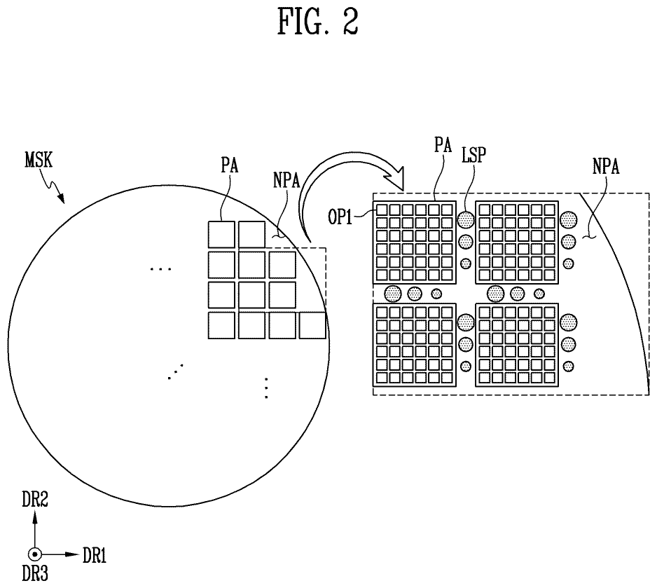

FIG. 2 is a plan view illustrating aspects of the deposition mask MSK of FIG. 1 according to some embodiments.

Referring to FIG. 2, the deposition mask MSK may have a circular shape in a plan view. However, the shape of the deposition mask MSK is not necessarily limited thereto, and the deposition mask MSK may have various other shapes in a plan view, for example, a rectangular or square shape, an irregular shape, and the like.

The deposition mask MSK may include a pattern area PA and a non-pattern area NPA excluding the pattern area PA. For example, the non-pattern area NPA may surround (e.g., in a periphery or outside a footprint of) the pattern area PA. The deposition mask MSK may be aligned to oppose the mother substrate MSB to be deposited. The deposition mask MSK may block the deposition material in some areas, and may not block the deposition material in other areas. Accordingly, the deposition material may be selectively deposited only on a region (e.g., a set or predetermined region) of the deposition target. For example, the deposition mask MSK may block the deposition material entirely in the non-pattern area NPA, and may not block the deposition material partially in the pattern area PA.

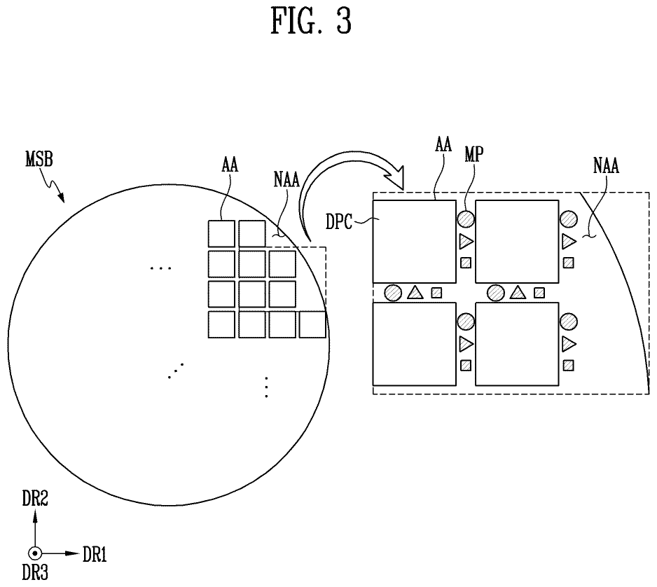

For example, the pattern area PA may be provided with first opening patterns OP1 and one second opening pattern (see a second opening pattern OP2 in FIG. 3) overlapping with the first opening patterns OP1. The deposition material may be provided to the deposition target through the second opening pattern OP2 and the first opening patterns OP1.

By using one deposition mask MSK, deposition may be performed simultaneously (or concurrently) on deposition targets. The pattern area PA may be provided as a plurality of pattern areas. For example, the pattern areas PA may be arranged along a first direction DR1 and a second direction DR2 intersecting the first direction DR1. The pattern areas PA may be spaced apart from each other. When the plurality of pattern areas PA are provided, each of the pattern areas PA may be provided with one second opening pattern OP2 and the first opening pattern OP1 overlapping the second opening pattern OP2.

According to some embodiments, the deposition mask MSK may include the first opening patterns OP1 located in the pattern area PA and lens patterns LSP located in the non-pattern area NPA. Accordingly, the lens patterns LSP may be spaced apart from the first opening patterns OP1 in a plan view. Further, the lens patterns LSP may be located between neighboring pattern areas PA in a plan view.

According to some embodiments, the lens patterns LSP may have different focal lengths. In other words, each of the lens patterns LSP may have a different focal length. Accordingly, when the deposition mask MSK is aligned to face the mother substrate MSB to be deposited, only some of the lens patterns LSP may be in focus across the entire area of the deposition mask MSK depending on a gap between the deposition mask MSK and the mother substrate MSB. Accordingly, the gap between the deposition mask MSK and the mother substrate MSB may be derived for each region in the entire area by using the focal length of the lens pattern LSP which is in focus among the lens patterns LSP.

In FIG. 2, the number of lens patterns LSP with different focal lengths is shown to be three, but embodiments according to the present disclosure are not limited thereto, and the shape of the lens patterns LSP is not limited thereto.

FIG. 3 is a plan view illustrating aspects of the mother substrate MSB of FIG. 1 according to some embodiments.

Referring to FIG. 3, the mother substrate MSB may have a shape and size corresponding to the shape and size of the deposition mask MSK. In other words, the mother substrate MSB may have a circular shape in a plan view. However, the shape of the mother substrate MSB is not necessarily limited thereto.

The mother substrate MSB may include an active area AA and an inactive area NAA excluding the active area AA. The active area AA of the mother substrate MSB may correspond to the pattern area PA of the deposition mask MSK, and the inactive area NAA of the mother substrate MSB may correspond to the non-pattern area NPA of the deposition mask MSK. The mother substrate MSB may be aligned to be opposite the deposition mask MSK. The mother substrate MSB may have a deposition material deposited in some regions, and may not have the deposition material deposited in other regions. Accordingly, the deposition material may be selectively deposited on a region (e.g., a set or predetermined region) of the mother substrate MSB. For example, the mother substrate MSB may not be entirely deposited with the deposition material in the inactive area NAA, but may be partially deposited with the deposition material only in a portion of the active area AA (e.g., a portion of the active area AA of the mother substrate MSB which overlaps with the first opening patterns OP1 of the deposition mask MSK). Accordingly, only display cells DPC located in the active area AA of the mother substrate MSB may be subsequently formed into a display panel, while the inactive area NAA may be removed.

According to some embodiments, the mother substrate MSB may include the display cells DPC located in the active area AA and mark patterns MP located in the inactive area NAA. Accordingly, the mark patterns MP may be spaced apart from the display cells DPC in a plan view. Further, the mark patterns MP may be located between neighboring display cells DPC in a plan view.

According to some embodiments, the mark patterns MP may have different shapes. Also, the number of mark patterns MP may be the same as the number of lens patterns LSP. When the deposition mask MSK is aligned to face the mother substrate MSB to be deposited, the mark patterns MP may be located at positions corresponding to the lens patterns LSP, respectively, on the deposition mask MSK. In the entire area of the deposition mask MSK, only some of the lens patterns LSP may form a focus on the corresponding mark patterns MP, depending on the gap between the deposition mask MSK and the mother substrate MSB. In other words, only the shape of the corresponding mark patterns MP may be clearly visible. Accordingly, by using the focal length of the lens pattern LSP corresponding to the mark pattern MP in which the focal point is formed among the mark patterns MP having different shapes, the gap between the area-specific deposition mask MSK and the mother substrate MSB may be derived for each region in the entire area.

In FIG. 3, the shapes of the mark patterns MP are shown as geometric figures, but embodiments are not limited thereto, and in other embodiments, the shapes of the mark patterns MP may be characters.

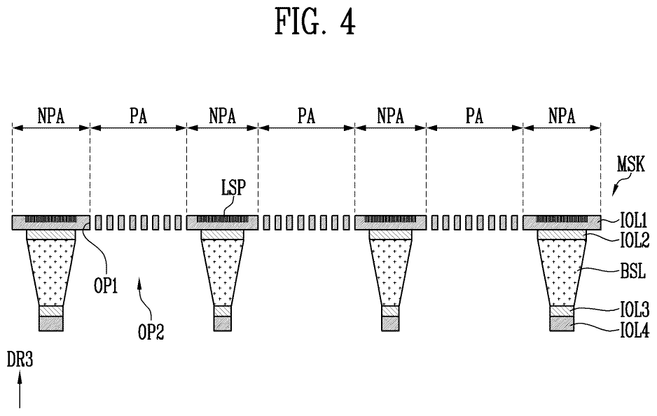

Referring now to FIGS. 4 to 10, the deposition mask MSK including the lens pattern LSP will be described in more detail.

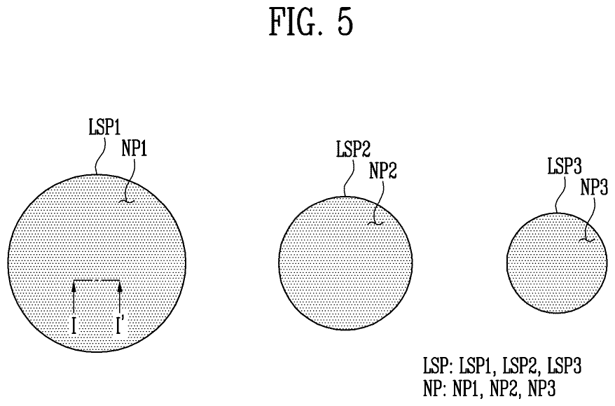

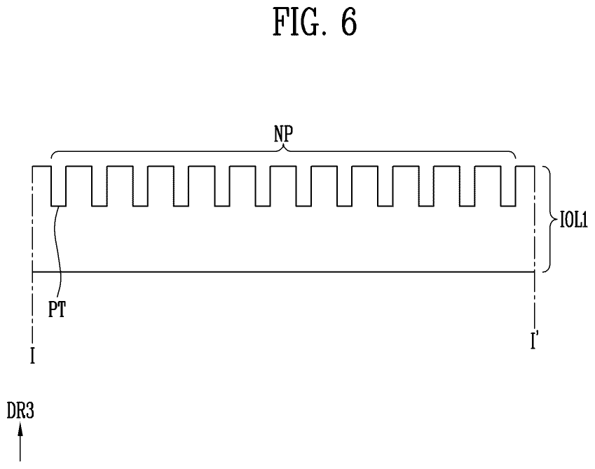

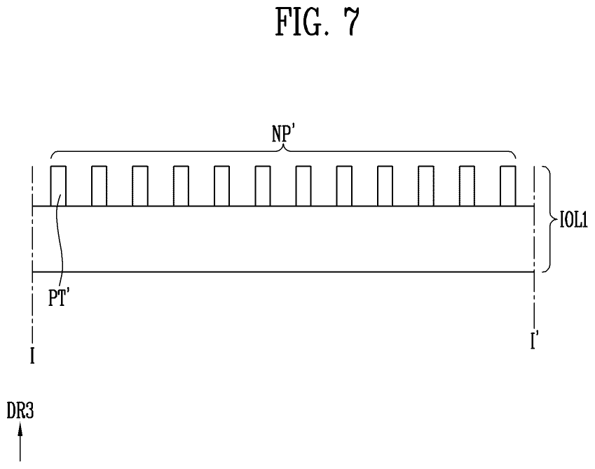

FIG. 4 is a cross-sectional view illustrating aspects of the deposition mask of FIG. 2 according to some embodiments. FIG. 5 is a plan view illustrating lens patterns having different focal lengths of FIG. 2. FIG. 6 is a cross-sectional view taken along the line I-I′ of FIG. 5. FIG. 7 shows further details of a cross-sectional view taken along the line I-I′ of FIG. 5, according to some embodiments.

Referring to FIG. 4, the deposition mask MSK may include a base layer BSL and first, second, third, and fourth inorganic layers IOL1, IOL2, IOL3, and IOL4.

The base layer BSL may include silicon. The base layer BSL defines the second opening pattern OP2 which overlaps with the pattern area PA. Thus, the base layer BSL may overlap only with the non-pattern area NPA.

The first inorganic layer IOL1 may be arranged on the base layer BSL. The first inorganic layer IOL1 may include silicon nitride. According to some embodiments, the first inorganic layer IOL1 may further include titanium dioxide (TiO₂) arranged on a silicon nitride layer. When the first inorganic layer IOL1 includes the titanium dioxide (TiO₂), the refractive index of the deposition mask MSK may be relatively improved. However, embodiments are not limited thereto.

The first inorganic layer IOL1 may include the first opening patterns OP1 and the lens patterns LSP. The first opening patterns OP1 may be located in the pattern area PA and may penetrate the first inorganic layer IOL1. Each of the lens patterns LSP may be located in the non-pattern area NPA and include a lens which refracts light to form a focal point.

The second inorganic layer IOL2 may be placed between the base layer BSL and the first inorganic layer IOL1. The second inorganic layer IOL2, like the base layer BSL, may only overlap with the non-pattern area NPA. That is, the second inorganic layer IOL2 may not overlap with the pattern area PA. The second inorganic layer IOL2 may include silicon oxide. However, embodiments are not limited thereto.

The third inorganic layer IOL3 may be arranged under the base layer BSL. The third inorganic layer IOL3, like the base layer BSL, may only overlap with the non-pattern area NPA. That is, the third inorganic layer IOL3 may not overlap with the pattern area PA. The third inorganic layer IOL3 may include the same material as the second inorganic layer IOL2. For example, the third inorganic layer IOL3 may include silicon oxide. However, embodiments are not limited thereto.

The fourth inorganic layer IOL4 may be arranged under the third inorganic layer IOL3. Like the base layer BSL, the fourth inorganic layer IOL4 may only overlap with the non-pattern area NPA. That is, the fourth inorganic layer IOL4 may not overlap with the pattern area PA. The fourth inorganic layer IOL4 may include the same material as the first inorganic layer IOL1. For example, the fourth inorganic layer IOL4 may include silicon nitride. However, embodiments are not limited thereto.

Referring further to FIG. 5, according to some embodiments, each of the lens patterns LSP may include a metasurface lens with a nano-pattern NP. For example, each of the lens patterns LSP may include the nano-pattern NP including nanoscale patterns PT (see FIG. 6). However, embodiments are not limited thereto, and in other embodiments, each of the lens patterns LSP may include a convex lens formed using a high refractive index material. Hereinafter, it is assumed and described that each of the lens patterns LSP includes a nano-pattern.

Referring further to FIG. 6, each of the patterns PT included in the nano-pattern NP may be defined as a recess. In other words, a portion of the first inorganic layer IOL1 may be removed at a nanoscale such that the patterns PT may have a groove shape etched from a top surface of the first inorganic layer IOL1 to a bottom surface thereof.

Referring further to FIG. 7, each of patterns PT′ included in a nano-pattern NP′ may be defined as a protrusion. That is, the patterns PT′ may be formed in the shape of pillars protruding from the top surface of the first inorganic layer IOL1 by forming nanoscale patterns on the first inorganic layer IOL1. Hereinafter, it is assumed and described that each of the lens patterns LSP includes the nano-pattern NP including the patterns PT defined as recesses.

Referring again to FIG. 5, according to some embodiments, the lens patterns LSP having different focal lengths may include the nano-patterns NP of different sizes, respectively. For example, when there are three lens patterns LSP1, LSP2, and LSP3 with different focal lengths, the larger the area, the larger the focal length. As used herein, the term ‘area’ may refer to a planar area. It is assumed that the nanoscale patterns PT included in each of first, second, and third nano-patterns NP1, NP2, and NP3 have the same size and shape.

Accordingly, the nano-pattern NP1 having the largest area may have the largest focal length. Furthermore, the focal length of the nano-pattern NP3 having the smallest area may be the smallest. Accordingly, the focal length of the lens pattern LSP may be controlled by adjusting the area of the nano-pattern NP.

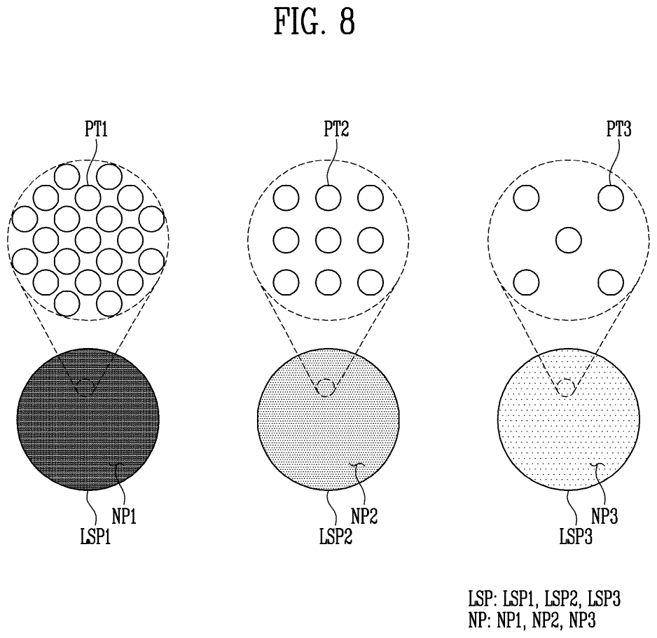

FIG. 8 is a plan view illustrating another embodiment of FIG. 5. The embodiments of FIG. 8 may be substantially the same as the embodiments of FIG. 5 except for a difference in the density between the lens patterns LSP.

Referring to FIG. 8, according to some embodiments, the lens patterns LSP having different focal lengths may include different densities of the nano-patterns NP, respectively. For example, when there are three lens patterns LSP1, LSP2, and LSP3 with different focal lengths, the greater the density of the patterns PT included in the nano-pattern NP, the greater the focal length. It is assumed that the first to third nano-patterns NP1 to NP3 have the same area, and the nano-sized patterns PT included in each of the first to third nano-patterns NP1 to NP3 have the same area and shape.

Accordingly, the nano-pattern NP1 having the largest density may have the largest focal length. Furthermore, the focal length of the nano-pattern NP3 having the smallest density may be the smallest. Accordingly, the focal length of the lens pattern LSP may be controlled by adjusting the density of the nano-pattern NP.

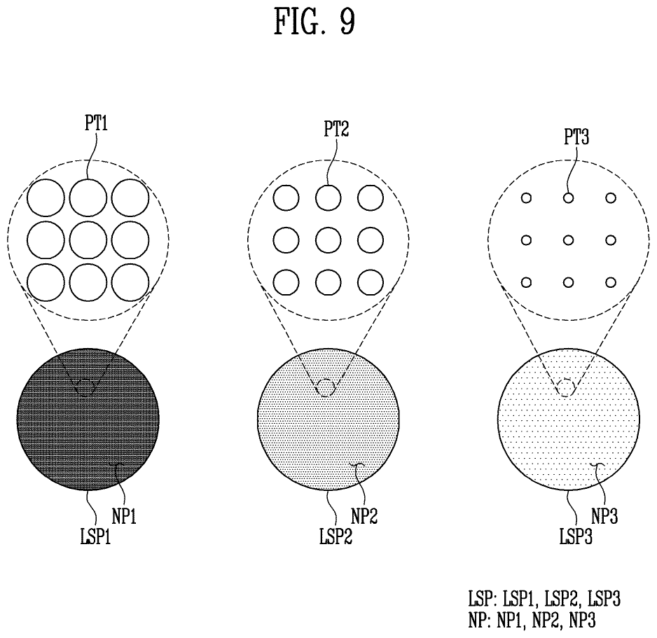

FIG. 9 is a plan view illustrating another embodiment of FIG. 8. The embodiments of FIG. 9 may be substantially the same as the embodiments of FIG. 8 except for the difference in area between the patterns PT included in the nano pattern NP.

Referring to FIG. 9, according to some embodiments, the lens patterns LSP having different focal lengths may include the nano-patterns NP, respectively, each of which includes the patterns PT having different areas. For example, when there are three lens patterns LSP1, LSP2, and LSP3 with different focal lengths, the larger the size of the patterns PT included in the nano-pattern NP, the larger the focal length may be. The first to third nano-patterns NP1 to NP3 are assumed to have the same area.

Accordingly, the focal length of the nano-pattern NP1 having the largest density may be the largest. Furthermore, the focal length of the nano-pattern NP3 having the smallest density may be the smallest. Accordingly, the focal length of the lens pattern LSP may be controlled by adjusting the density of the nano-pattern NP.

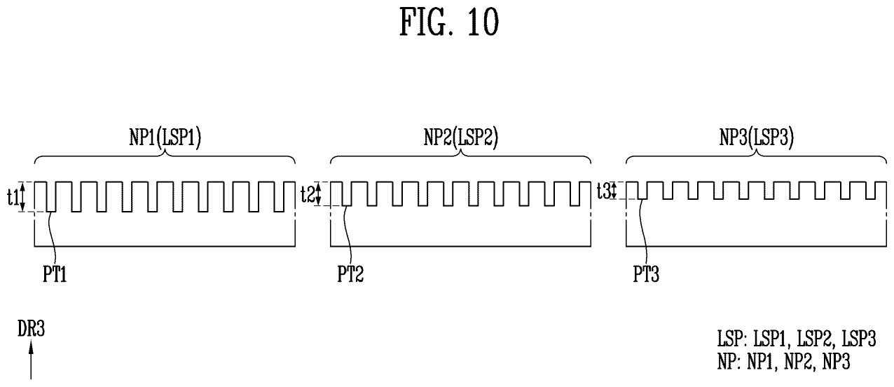

FIG. 10 is a plan view illustrating another embodiment of FIG. 5. The embodiments of FIG. 10 may be substantially the same as the embodiments of FIG. 5 except for the difference in area between the nano-patterns NP and the difference in thickness between the nano-patterns NP. Hereinafter, the thickness of the nano-pattern NP may refer to the length or depth in a third direction DR3 of the nano-pattern NP.

Referring to FIG. 10, according to some embodiments, the lens patterns LSP having different focal lengths may include the nano-patterns NP having different thicknesses t1, t2, and t3, respectively. For example, when there are three lens patterns LSP1, LSP2, and LSP3 with different focal lengths, the larger the thickness of the nano-patterns NP, the larger the focal length. It is assumed that each of the first to third nano-patterns NP1 to NP3 has the same area.

Accordingly, the focal length of the first nano-pattern NP1 having the largest thickness t1 may be the largest. Further, the focal length of the third nano-pattern NP3 having the smallest thickness t3 may be the smallest. Accordingly, by adjusting the thickness of the nano-pattern NP, the focal length of the lens pattern LSP may be controlled.

According to some embodiments, each of the lens patterns LSP having different focal lengths may include the nano-pattern NP including the patterns PT having different shapes. When each of the nano-patterns NP includes the patterns PT having different shapes, the nano-patterns NP may cause directionality in the refraction, thereby controlling not only the focal length but also the focal position.

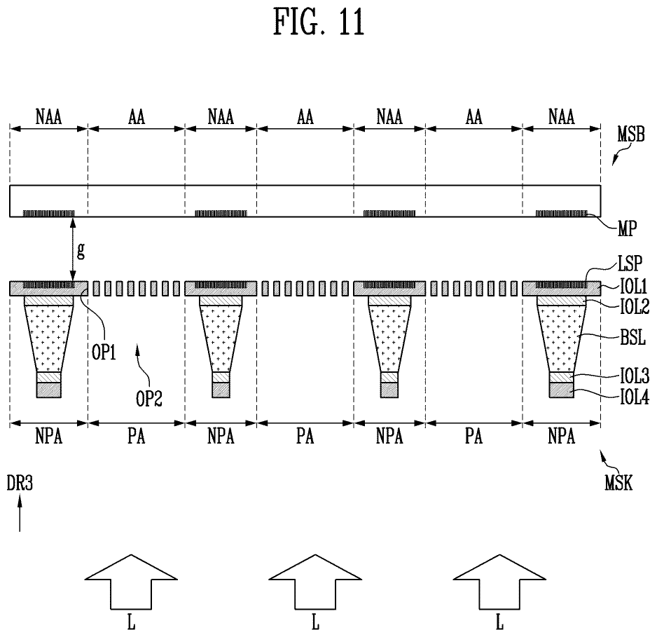

FIG. 11 is a diagram illustrating a method of measuring a gap between a mother substrate and a deposition mask according to embodiments of the present disclosure. For example, the method of measuring a gap as described with reference to FIG. 11 may be performed using the deposition mask MSK of FIG. 2 and the mother substrate MSB of FIG. 3. Accordingly, some redundant descriptions may be omitted.

Referring to FIGS. 2, 3, and 11, the mother substrate MSB including the mark patterns MP located at corresponding positions to the lens patterns LSP may be positioned on the deposition mask MSK including the first opening pattern OP1 located in the pattern area PA and the lens patterns LSP located in the non-pattern area NPA and having different focal lengths.

For example, the deposition mask MSK may include the lens patterns LSP having different focal lengths, and the lens patterns LSP may include the nano-patterns NP including the nano-sized patterns PT. The focal length of the lens pattern LSP may be controlled by adjusting at least one of the density of the nano-patterns NP (see FIGS. 8 and 9), the area of the nano-patterns NP (see FIG. 5), the thickness of the nano-patterns NP (see FIG. 10), or the area of each of the patterns PT included in the nano-pattern NP (see FIG. 9).

Further, the mother substrate MSB may include the mark patterns MP having different shapes. Because neighboring mark patterns MP have different shapes, the mark patterns MP may be distinguishable from each other.

The mother substrate MSB may be positioned on the deposition mask MSK such that the pattern area PA and the active area AA may overlap with each other, the non-pattern area NPA and the inactive area NAA may overlap with each other, and the lens patterns LSP and the mark patterns MP may overlap with each other. The lens patterns LSP and the mark patterns MP correspond to each other. Thus, the number of lens patterns LSP and the number of mark patterns MP may be the same.

Light L may be irradiated in a direction from the deposition mask MSK toward the mother substrate MSB. According to some embodiments, the light L may have a wavelength of about 1050 nanometers or greater. When the light L has a wavelength about 1050 nanometers or greater and penetrates the base layer BSL, the light L may reach the lens pattern LSP located in the non-pattern area NPA. When the light L has a wavelength of less than about 1050 nanometers, the light L may not penetrate the base layer BSL located in the non-pattern area NPA. As a result, the light L may not reach the lens pattern LSP and a focus may not be formed due to the lens pattern LSP.

When the light L is irradiated in the direction from the deposition mask MSK toward the mother substrate MSB, there may be the lens pattern LSP in which a focus is formed on a corresponding mark pattern MP among the plurality of lens patterns LSP. That is, the corresponding mark pattern MP may be clearly observed as being in focus, unlike the neighboring mark patterns MP, and has a shape which is distinct from the neighboring mark patterns MP. Therefore, it may be identified which lens pattern LSP among the neighboring lens patterns LSP corresponds to the corresponding mark pattern MP.

Accordingly, when the lens pattern LSP corresponding to the in-focus mark pattern MP is identified, a gap g between the deposition mask MSK and the mother substrate MSB may be derived using the focal length of the lens pattern LSP. That is, the focal length of the lens pattern LSP may correspond to the gap g between the deposition mask MSK and the mother substrate MSB in the corresponding region.

According to some embodiments, the gap g between the deposition mask MSK and the mother substrate MSB may be derived using the focal length of the lens pattern LSP corresponding to the focused mark pattern MP. When the lens patterns LSP are distributed throughout the non-pattern area NPA of the deposition mask MSK and the mark patterns MP corresponding to the lens patterns LSP are distributed throughout the inactive area NAA of the mother substrate MSB, the gap g between the deposition mask MSK and the mother substrate MSB may be derived in each region of the entire inactive area NAA of the mother substrate MSB. In other words, because the gap g between the deposition mask MSK and the mother substrate MSB may be derived for each region, the uniformity of the gap g between the deposition mask MSK and the mother substrate MSB may be measured in the entire region. As a result, because the gap g between the deposition mask MSK and the mother substrate MSB may be uniformly controlled, a deposition shadow phenomenon may be relatively reduced, and the uniformity of the deposited material deposited on the mother substrate MSB may be relatively improved. Thus, the reliability of the deposited mother substrate MSB using the method of measuring a gap according to some embodiments may be relatively improved.

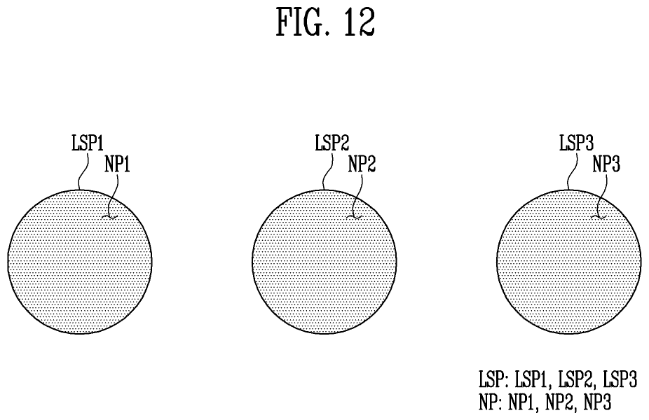

FIG. 12 is a plan view illustrating another embodiment of FIG. 5. The embodiments of FIG. 12 may be substantially the same as the embodiments of FIG. 5 except for the difference in area between the lens patterns LSP.

Referring to FIGS. 11 and 12, according to some embodiments, the lens patterns LSP included in the first inorganic layer IOL1 may have the same focal length.

For example, the three lens patterns LSP1, LSP2, and LSP3 having the same focal length may include the nano-patterns NP having the same area, density, and thickness, and including the patterns PT having the same area and shape.

The wavelength of the light L irradiated in the direction from the deposition mask MSK toward the mother substrate MSB may change continuously. As the wavelength of the irradiated light L varies, the focal length of the lens patterns LSP may vary. For example, when the light L with a shorter wavelength is irradiated, the focal length of the lens patterns LSP may be decreased. When the light L with a longer wavelength is irradiated, the focal length of the lens patterns LSP may be increased.

As a result, when the wavelength of the irradiated light L is changed, the mark patterns MP corresponding to the lens patterns LSP may come into focus in the light L having a wavelength (e.g., a set or predetermined wavelength). The gap g between the mother substrate MSB and the deposition mask MSK may be derived by using the focal length of the lens pattern LSP in the light L having the corresponding wavelength. That is, the focal length of the lens pattern LSP may correspond to the gap g between the deposition mask MSK and the mother substrate MSB.

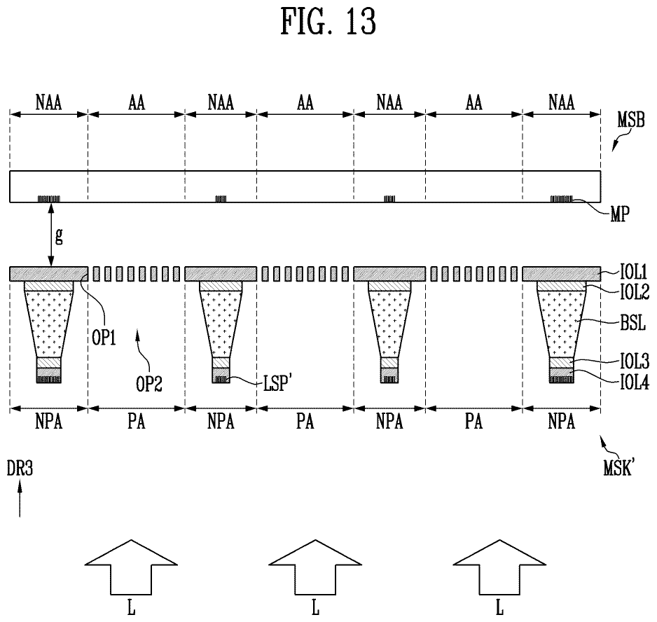

FIG. 13 is a cross-sectional view illustrating another example of FIG. 11. The embodiments of FIG. 13 may be substantially the same as the embodiments of FIG. 11 except for the location of lens patterns LSP′.

Referring to FIG. 13, according to some embodiments, the lens patterns LSP′ may be included in the fourth inorganic layer IOL4 arranged under the base layer BSL. Further, the lens patterns LSP′ may have different focal lengths. The fourth inorganic layer IOL4, the third inorganic layer IOL3, the base layer BSL, the second inorganic layer IOL2, and the first inorganic layer IOL1 may be arranged between the lens patterns LSP′ and the mark patterns MP, thereby widening the gap between the lens patterns LSP′ and the mark patterns MP. Accordingly, the lens pattern LSP′ may have a longer focal length than conventionally. Accordingly, even when the lens pattern LSP′ has a long focal length, the gap g between a deposition mask MSK′ and the mother substrate MSB may be measured using the lens pattern LSP′ and the mark pattern MP.

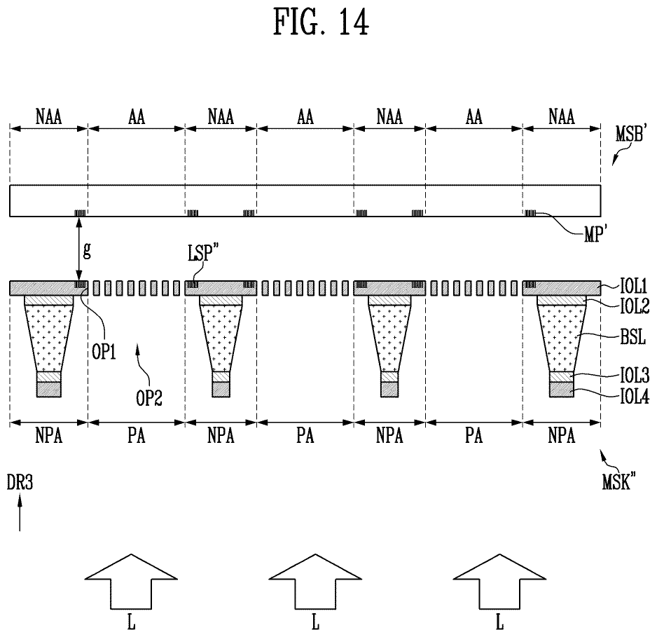

FIG. 14 is a cross-sectional view illustrating another example of FIG. 11. The embodiments of FIG. 14 may be substantially the same as the embodiments of FIG. 11 except for the location of lens pattern LSP″.

Referring to FIG. 14, according to some embodiments, the light L may be irradiated in a direction from a deposition mask MSK″ toward a mother substrate MSB′. According to some embodiments, the light L may be visible light. For example, the light L may have a wavelength of greater than or equal to about 300 nanometers and less than or equal to about 800 nanometers. The light L may not readily penetrate the base layer BSL. Accordingly, the lens patterns LSP″ may be arranged in the non-pattern area NPA but may not overlap with the base layer BSL. That is, the lens patterns LSP″ may be spaced apart from the base layer BSL on the plane.

Because the lens patterns LSP″ are positioned in the non-pattern area NPA and do not overlap with the base layer BSL, the visible light L may reach the lens patterns LSP″ which do not overlap with the base layer BSL even when the visible light does not penetrate the base layer BSL. Accordingly, the gap g between the deposition mask MSK″ and the mother substrate MSB′ may be measured using the lens patterns LSP″ and the corresponding mark patterns MP″.

A deposition mask and a method of measuring a gap according to some embodiments may be applied to various electronic devices. An electronic device according to some embodiments is manufactured using the deposition mask and the method of measuring the gap as described above, and may further include a module or device having other additional functions besides a display device.

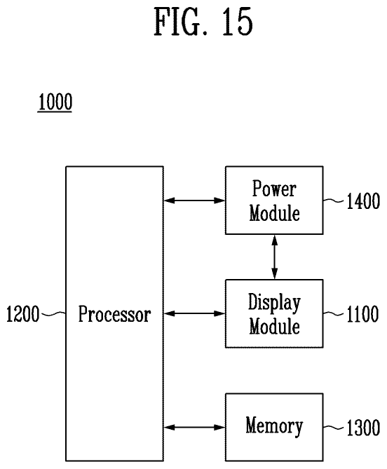

FIG. 15 is a block diagram of an electronic device 1000 according to some embodiments.

Referring to FIG. 15, the electronic device 1000 may include a display module 1100, a processor 1200, a memory 1300, and a power module 1400.

The processor 1200 may include at least one of a central processing unit (CPU), an application processor (AP), a graphic processing unit (GPU), a communication processor (CP), an image signal processor (ISP), or a controller.

The memory 1300 may store data and/or information used to operate the processor 1200 or the display module 1100. When the processor 1200 executes an application stored in the memory 1300, image data signals and/or input control signals may be transferred to the display module 1100. The display module 1100 may process the provided signals and output image information on a display screen.

The power module 1400 may include a power supply module, such as a power adapter or a battery device, and a power conversion module. The power conversion module converts power supplied by the power supply module and generates power to operate the electronic device 1000.

At least one of the above-described components of the electronic device 1000 may be included in the display device according to embodiments as described above. In addition, in terms of functionality, some of the individual modules included in one module may be included in a display device and others may be provided separately from the display device. For example, the display device may include the display module 1100, and the processor 1200, the memory 1300, and the power module 1400 may be provided as other devices in the electronic device 1000, not the display device.

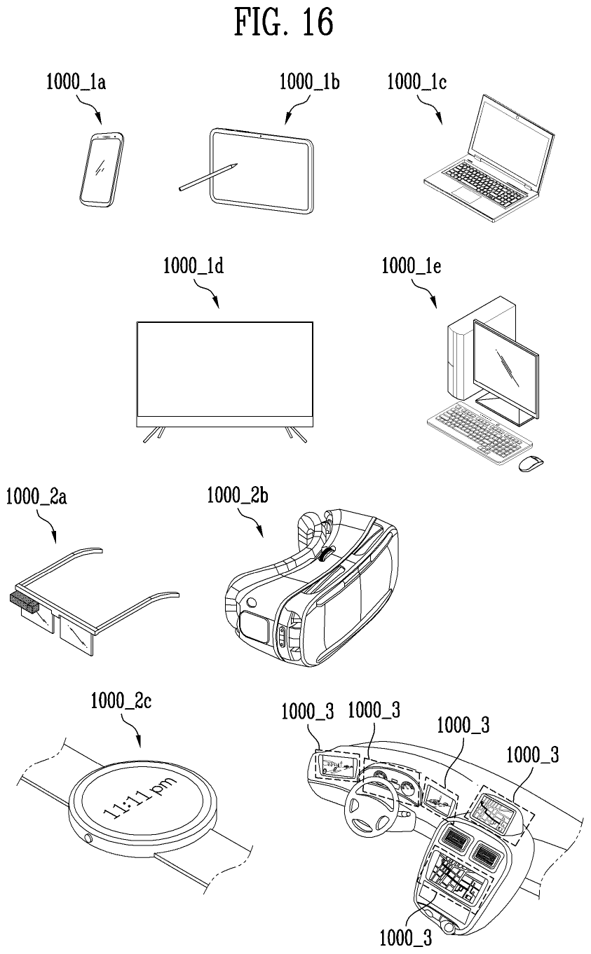

FIG. 16 shows schematic views of various embodiments of the electronic device 1000.

Referring to FIG. 16, various types of electronic devices to which embodiments of a display device are applied may include an electronic device to display images such as a smartphone 1000_1a, a tablet PC 1000_1b, a laptop computer 1000_1c, a television (TV) 1000_1d, and a desktop monitor 1000_1e, a wearable electronic device including a display module such as smart glasses 1000_2a, a head-mounted display (HMD) 1000_2b, and a smart watch 1000_2c, and an automotive electronic device 1000_3 including a display module such as a center information display (CID) arranged at the instrument cluster, the center fascia, and the dashboard of a vehicle, and a room mirror display.

According to the above-described embodiments, a gap between a deposition mask and a mother substrate may be derived using a focal length of a lens pattern corresponding to a focused mark pattern. Because the gap between the deposition mask and the mother substrate may be derived for each region, the uniformity of the gap between the deposition mask and the mother substrate may be measured in the entire region. As a result, because the gap between the deposition mask and the mother substrate may be uniformly controlled, a deposition shadow phenomenon may be relatively reduced, and the uniformity of a material deposited on the mother substrate may be relatively improved. Thus, the reliability of the deposited mother substrate using the method of measuring the gap according to some embodiments may be relatively improved.

The embodiments described above are provided to explain the present disclosure, but these embodiments are not intended to limit the scope of the present disclosure. It will be understood by those skilled in the art that various changes, substitutions, and alternatives may be made therein without departing from the scope of the disclosure as set forth by the claims and their equivalents. Therefore, the technical scope of embodiments according to the present disclosure may be determined based on the scope of the accompanying claims and their functional equivalents.

What is claimed is:

1. A deposition mask, comprising:
a base layer including silicon;
an inorganic layer on the base layer,
wherein the inorganic layer comprises an opening pattern in a pattern area, and lens patterns in a non-pattern area excluding the pattern area and having different focal lengths.

2. The deposition mask of claim 1, wherein each of the lens patterns having the different focal lengths comprises a nano-pattern including patterns having a nanoscale size.

3. The deposition mask of claim 2, wherein the lens patterns having the different focal lengths comprise nano-patterns of different densities, respectively.

4. The deposition mask of claim 2, wherein the lens patterns having the different focal lengths comprise nano-patterns of different areas, respectively.

5. The deposition mask of claim 2, wherein each of the lens patterns having the different focal lengths comprises a nano-pattern including patterns of different areas.

6. The deposition mask of claim 2, wherein the lens patterns having the different focal lengths comprise nano-patterns having different thicknesses, respectively.

7. The deposition mask of claim 2, wherein each of the nano-patterns comprise a recess.

8. The deposition mask of claim 2, wherein each of the nano-patterns comprise a protrusion.

9. The deposition mask of claim 1, wherein the inorganic layer comprises titanium dioxide (TiO₂).

10. A method of measuring a gap, the method comprising:
aligning a mother substrate including mark patterns at positions corresponding to lens patterns on a deposition mask including an opening pattern located in a pattern area, and the lens patterns being in a non-pattern area excluding the pattern area and having different focal lengths;
irradiating light in a direction from the deposition mask toward the mother substrate; and
deriving a gap between the deposition mask and the mother substrate using a focal length of a lens pattern in which a focus is formed on a corresponding mark pattern among the lens patterns.

11. The method of claim 10, wherein each of the lens patterns comprises a nano-pattern including patterns having a nanoscale size.

12. The method of claim 11, further comprising controlling the focal length of the lens pattern by adjusting at least one of a density of the nano-pattern, an area of the nano-pattern, or a thickness of the nano-pattern.

13. The method of claim 10, wherein the mother substrate comprises a display cell in an active area, and the mark patterns in an inactive area excluding the active area and having different shapes.

14. The method of claim 13, wherein in the aligning of the mother substrate on the deposition mask, the mother substrate is on the deposition mask such that the pattern area and the active area overlap each other, and the lens patterns and the mark patterns overlap each other.

15. The method of claim 14, wherein a number of lens patterns and a number of mark patterns are equal.

16. The method of claim 10, wherein the light has a wavelength of 1050 nanometers or greater.

17. The method of claim 10, wherein the light is visible light.

18. The method of claim 17, wherein the deposition mask comprises:
a base layer including silicon; and
an inorganic layer on the base layer and defining the opening pattern and the lens patterns,
wherein the lens patterns are spaced apart from the base layer in a plane.

19. An electronic device, comprising:
a processor; and
a display device configured to display an image under control of the processor,
wherein the display device is manufactured using the deposition mask of claim 1.
